(19) United States
(12) Patent Application Publication
(10) Pub. No.: US 2019/0237305 A1
(43) Pub. Date: Aug. 1, 2019

(54) METHOD FOR APPLYING DC VOLTAGE AND PLASMA PROCESSING APPARATUS

(71) Applicant: TOKYO ELECTRON LIMITED, Tokyo (JP)

(72) Inventors: Hiroshi TSUJIMOTO, Miyagi (JP); Toshikatsu TOBANA, Miyagi (JP)

(73) Assignee: TOKYO ELECTRON LIMITED, Tokyo (JP)

(21) Appl. No.: 16/257,205

(22) Filed: Jan. 25, 2019

(30) Foreign Application Priority Data
Jan. 26, 2018 (JP) 2018-011776

(51) Int. Cl. H01J 37/32; H01L 21/683

(52) U.S. Cl. CPC H01J 37/32541; H01L 21/6833; H01J 37/32577; H01J 37/32027

(57) ABSTRACT

In a method for applying a DC voltage to an electrode of a plasma processing apparatus, plasma of a gas is generated in an inner space of a chamber and an absolute value of a negative DC voltage applied from a DC power supply to the electrode that forms a part of the chamber or is provided in the inner space during the generation of the plasma is increased. A first voltage value is specified, the first voltage value being a voltage value measured at the electrode when a current starts to flow in the electrode during the increase of the absolute value of the negative DC voltage. A value of the DC voltage applied from the DC power supply to the electrode during the generation of the plasma is set to a second voltage value that is a sum of the first voltage value and a specified value.

### CROSS-REFERENCE TO RELATED APPLICATIONS

This application claims priority to Japanese Patent Application No. 2018-011776 filed on Jan. 26, 2018, the entire contents of which are incorporated herein by reference.

### FIELD OF THE INVENTION

The present disclosure relates to a method for applying a DC voltage and a plasma processing apparatus.

### BACKGROUND OF THE INVENTION

In manufacturing electronic devices, plasma processing is performed on a substrate by using a plasma processing apparatus. In general, the plasma processing apparatus includes a chamber, a supporting table, and a high frequency power supply. The supporting table is provided in an inner space of the chamber. The supporting table has a lower electrode. The high frequency power supply is electrically connected to the lower electrode. The plasma processing is performed in a state where the substrate is mounted on the supporting table. In the plasma processing, gas is supplied to the inner space of the chamber and excited by the high frequency power to generate plasma in the inner space. During the plasma processing, a focus ring is arranged to surround the substrate. The focus ring improves in-plane uniformity of the plasma processing.

The thickness of the focus ring is decreased by the plasma processing. There is suggested a technique for applying a voltage to a focus ring to secure in-plane uniformity of plasma processing even if the thickness of the focus ring becomes smaller than an initial thickness thereof. Such a technique is described in, e.g., Japanese Patent Application Publication No. 2005-203489, in which a high frequency power is supplied from a high frequency power supply to a lower electrode and the focus ring. When a voltage is applied to the focus ring by supplying the high frequency power, the state of plasma in an inner space is adjusted.

In order to adjust the state of the plasma, it is considered to apply a negative DC voltage to the electrode of the plasma processing apparatus. However, depending on the value of the voltage applied to the electrode, the state of the plasma may not be changed, which makes the adjustment of the plasma state impossible.

### SUMMARY OF THE INVENTION

In accordance with an aspect, there is provided a method for applying a DC voltage to an electrode of a plasma processing apparatus. The method comprises: (i) generating plasma of a gas in an inner space of a chamber; (ii) increasing an absolute value of a negative DC voltage applied from a DC power supply to the electrode that forms a part of the chamber or is provided in the inner space during the generation of the plasma; (iii) specifying a first voltage value that is a voltage value measured at the electrode when a current starts to flow in the electrode during the increase of the absolute value of the negative DC voltage; and (iv) setting a value of the DC voltage applied from the DC power supply to the electrode during the generation of the plasma to a second voltage value that is a sum of the first voltage value and a specified value.

In accordance with another aspect, there is provided a plasma processing apparatus comprising a chamber, a high frequency power supply, a DC power supply, a first measuring device, a second measuring device and a control unit. The high frequency power supply is configured to generate a high frequency power for exciting a gas supplied to an inner space of the chamber. The DC power supply is electrically connected to an electrode that forms a part of the chamber or is provided in the inner space. The first measuring device is configured to measure a current at the electrode. The second measuring device is configured to measure a voltage at the electrode. The control unit is configured to control a negative DC voltage applied from the DC power supply to the electrode. The control unit performs processes including: (i) controlling the DC power supply to increase an absolute value of the negative DC voltage applied to the electrode during generation of plasma in the inner space; (ii) specifying a time at which a current starts to flow in the electrode from the measurement value obtained by the first measuring device during the increase of the absolute value of the DC voltage and specifying a first voltage value at the electrode at the specified time by using the second measuring device; and (iii) controlling the DC power supply to set a value of the DC voltage applied to the electrode during the generation of the plasma to a second voltage value that is a sum of the first voltage value and a specified value.

### BRIEF DESCRIPTION OF THE DRAWINGS

The objects and features of the present disclosure will become apparent from the following description of embodiments, given in conjunction with the accompanying drawings, in which:

FIG. 1 is a flowchart of a method of applying a DC voltage according to an embodiment;

FIG. 2 schematically shows a plasma processing apparatus according to an embodiment;

FIG. 3 is a partially enlarged cross sectional view of a supporting table and a focus ring of the plasma processing apparatus shown in FIG. 1;

FIG. 4 is a timing chart related to the method shown in FIG. 1; and

FIG. 5 is a graph showing the relation between an absolute value of a negative DC voltage at a focus ring of the plasma processing apparatus shown in FIG. 1 and a current at the focus ring.

### DETAILED DESCRIPTION OF THE EMBODIMENTS

Hereinafter, embodiments will be described in detail with reference to the accompanying drawings. Like reference numerals will be given to like or corresponding parts throughout the drawings.

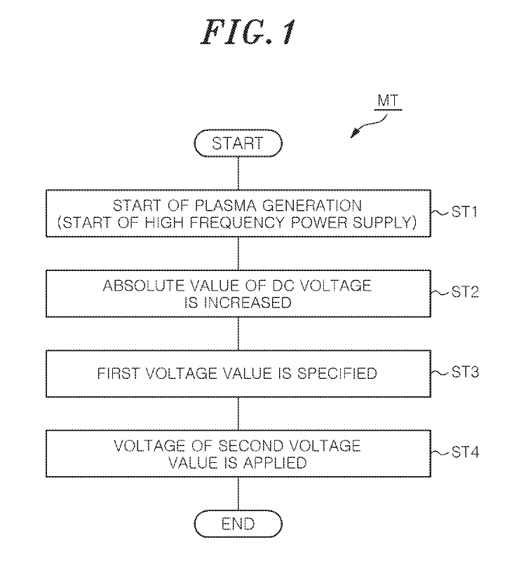

FIG. 1 is a flowchart of a method of applying a DC voltage according to an embodiment. In the method MT shown in FIG. 1, a DC voltage is applied to an electrode of a plasma processing apparatus to adjust the state of plasma generated in an inner space of a chamber of the plasma processing apparatus.

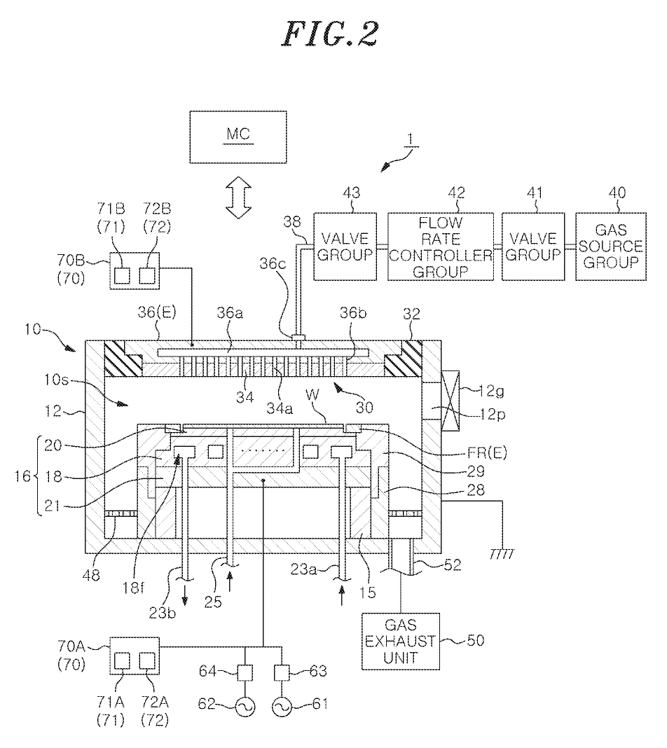

FIG. 2 schematically shows a plasma processing apparatus according to an embodiment. The method MT can be performed by using the plasma processing apparatus 1 shown in FIG. 2. The plasma processing apparatus 1 is a capacitively coupled plasma processing apparatus.

The plasma processing apparatus 1 includes a chamber 10. The chamber 10 provides an inner space 10s. In one embodiment, the chamber 10 includes a chamber body 12. The chamber body 12 has a substantially cylindrical shape. The inner space 10s is formed in the chamber body 12. The chamber body 12 is made of, e.g., aluminum. The chamber body 12 is electrically grounded. A plasma resistant film is formed on an inner wall surface of the chamber body 12, i.e., the wall surface defining the inner space 10s. This film may be a film formed by anodic oxidation treatment or a ceramic film made of yttrium oxide.

A passage 12p is formed at the sidewall of the chamber body 12. The substrate W is transferred between the inner space 10s and the outside of the chamber 10 through the passage 12p. A gate valve 12g is provided along the sidewall of the chamber body 12 to open and close the passage 12p.

A supporting table 16 is provided in the inner space 10s. The supporting table 16 is configured to support the substrate W mounted thereon. The supporting table 16 is supported by a supporting part 15. The supporting part 15 extends upward from the bottom portion of the chamber body 12. The supporting part 15 has a substantially cylindrical shape and made of an insulating material such as quartz.

In one embodiment, the supporting table 16 includes a lower electrode 18 and an electrostatic chuck 20. The supporting table 16 may further include an electrode plate 21. The electrode plate 21 is made of a conductive material such as aluminum and has a substantially disc shape. The lower electrode 18 is provided on the electrode plate 21. The lower electrode 18 is made of a conductive material such as aluminum, and has a substantially disc shape. The lower electrode 18 is electrically connected to the electrode plate 21.

A flow path 18f is formed in the lower electrode 18. A heat exchange medium flows through the flow path 18f. As for the heat exchange medium, a liquid coolant or a coolant (e.g., Freon) that is vaporized to cool the lower electrode 18 is used. A circulation device (e.g., a chiller unit) for the heat exchange medium is connected to the flow path 18f. The circulation device is provided outside the chamber 10. The heat exchange medium is supplied to the flow path 18f from the circulation device through a pipe 23a. The heat exchange medium supplied to the flow path 18f is returned to the circulation device through a pipe 23b.

The electrostatic chuck 20 is provided on the lower electrode 18. When the substrate W is processed in the inner space 10s, the substrate W is mounted on and held by the electrostatic chuck 20. The electrostatic chuck 20 has a main body and an electrode. The main body of the electrostatic chuck 20 is made of an insulator. The electrode of the electrostatic chuck 20 is a film-shaped electrode and is provided in the main body of the electrostatic chuck 20. A DC power supply is electrically connected to the electrode of the electrostatic chuck 20. When a voltage is applied from the DC power supply to the electrode of the electrostatic chuck 20, an electrostatic attractive force is generated between the electrostatic chuck 20 and the substrate W mounted on the electrostatic chuck 20. Due to the electrostatic attractive force, the substrate W is attracted to and held on the electrostatic chuck 20.

In one embodiment, the plasma processing apparatus 1 further includes a gas supply line 25. A heat transfer gas, e.g., He gas, is supplied through the gas supply line 25 from a gas supply unit to a gap between the upper surface of the electrostatic chuck 20 and the backside (lower surface) of the substrate W.

In one embodiment, the plasma processing apparatus 1 further includes a tubular member 28 and an insulating member 29. The tubular member 28 extends upward from the bottom portion of the chamber body 12. The tubular member 28 extends along the outer periphery of the supporting part 15. The tubular member 28 is made of a conductive material and has a substantially cylindrical shape. The tubular member 28 is electrically grounded. The insulating member 29 is provided on the tubular member 28. The insulating member 29 is made of an insulating material. The insulating member 29 is made of ceramic, e.g., quartz. The insulating member 29 has a substantially cylindrical shape. The insulating member 29 extends along the outer peripheries of the electrode plate 21, the lower electrode 18 and the electrostatic chuck 20.

A focus ring FR is disposed on an outer peripheral region of the electrostatic chuck 20. The focus ring FR has a substantially annular plate shape. The focus ring FR has conductivity. The focus ring FR is made of, e.g., silicon. The focus ring FR is disposed to surround the edge of the substrate W. The focus ring FR is an example of the electrode E of the plasma processing apparatus 1 and is provided in the inner space 10s. The focus ring FR is electrically connected to a DC power supply 70A as will be described later.

The plasma processing apparatus 1 further includes an upper electrode 30. The upper electrode 30 is provided above the supporting table 16. The upper electrode 30 blocks an upper opening of the chamber body 12 in cooperation with a member 32. The member 32 has an insulating property. The upper electrode 30 is held at an upper portion of the chamber body 12 through the member 32. The upper electrode 30 is another example of the electrode E of the plasma processing apparatus 1 and forms a part of the chamber 10. As will be described later, a DC power supply 70B is electrically connected to the upper electrode 30.

The upper electrode 30 includes a ceiling plate 34 and a holder 36. A bottom surface of the ceiling plate 34 defines the inner space 10s. The ceiling plate 34 is provided with a plurality of gas injection holes 34a. The gas injection holes 34a penetrate through the ceiling plate 34 in a plate thickness direction (vertical direction). The ceiling plate 34 is made of, e.g., silicon, but is not limited thereto. Alternatively, the ceiling plate 34 may have a structure in which a plasma resistant film is formed on a surface of an aluminum base material. This film may be a film formed by anodic oxidation treatment or a ceramic film made of yttrium oxide.

The holder 36 detachably holds the ceiling plate 34. The holder 36 is made of a conductive material such as aluminum. A gas diffusion space 36a is provided inside the holder 36. A plurality of gas holes 36b extends downward from the gas diffusion space 36a. The gas holes 36b communicate with the respective gas injection holes 34a. A gas inlet port 36c is formed in the holder 36. The gas inlet port 36c is connected to the gas diffusion space 36a. A gas supply line 38 is connected to the gas inlet port 36c.

A gas source group 40 is connected to the gas supply line 38 through a valve group 41, a flow rate controller group 42 and a valve group 43. The gas source group 40 includes a plurality of gas sources. Each of the valve group 41 and the valve group 43 includes a plurality of valves (e.g., on-off valves). The flow rate controller group 42 includes a plurality of flow rate controllers. Each of the flow rate controllers of the flow rate controller group 42 is a mass flow controller or a pressure control type flow controller. The gas sources of the gas source group 40 are respectively connected to the gas supply line 38 through corresponding valves of the valve group 41, corresponding flow controllers of the flow rate control group 42, and corresponding valves of the valve group 43. The plasma processing apparatus 1 can supply gases from one or more gas sources selected among the plurality of gas sources of the gas source group 40 to the inner space 10s at individually controlled flow rates.

A baffle plate 48 is provided between the tubular member 28 and the sidewall of the chamber body 12. The baffle plate 48 may be formed by coating ceramic such as yttrium oxide on an aluminum base material, for example. A plurality of through-holes is formed in the baffle plate 48. Below the baffle plate 48, a gas exhaust line 52 is connected to the bottom portion of the chamber body 12. A gas exhaust unit 50 is connected to the gas exhaust line 52. The gas exhaust unit 50 includes a pressure controller such as an automatic pressure control valve, and a vacuum pump such as a turbo molecular pump or the like, and thus can decrease a pressure in the inner space 10s.

The plasma processing apparatus 1 further includes a first high frequency power supply 61. The first high frequency power supply 61 generates a first high frequency power for plasma generation. The first high frequency power has a frequency ranging from 27 to 100 MHz, e.g., 60 MHz. The first high frequency power supply 61 is connected to the lower electrode 18 via a first matching unit 63 and the electrode plate 21. The first matching unit 63 has a matching circuit for matching an output impedance of the first high frequency power supply 61 and an impedance of a load side (the lower electrode 18 side). The first high frequency power supply 61 may not be electrically connected to the lower electrode 18 and may be connected to the upper electrode 30 via the first matching unit 63.

The plasma processing apparatus 1 further includes a second high frequency power supply 62. The second high frequency power supply 62 generates a second high frequency power for attracting ions to the substrate W (for bias). The frequency of the second high frequency power is lower than the frequency of the first high frequency power. The frequency of the second high frequency power is within a range from 400 kHz to 13.56 MHz, e.g., 400 kHz. The second high frequency power supply 62 is connected to the lower electrode 18 via a second matching unit 64 and the electrode plate 21. The second matching unit 64 has a matching circuit for matching an output impedance of the second high frequency power supply 62 and the impedance of the load side (the lower electrode 18 side).

In the plasma processing apparatus 1, a gas is supplied to the inner space 10s. Then, the gas is excited in the inner space 10s by supplying the first high frequency power and/or the second high frequency power. As a result, plasma is generated in the inner space 10s. The substrate W is processed by ions and/or radicals in the generated plasma.

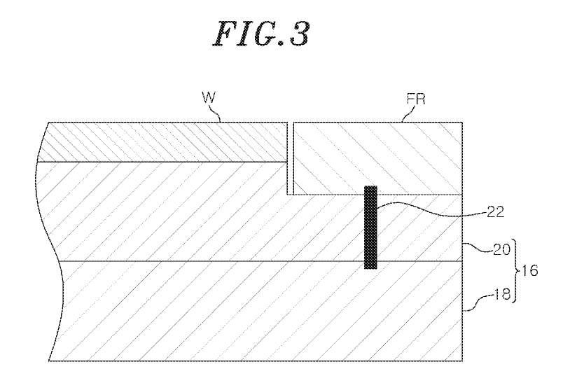

The plasma processing apparatus 1 further includes a DC power supply 70A. The DC power supply 70A is electrically connected to the focus ring FR. The DC power supply 70A generates a negative DC voltage to be applied to the focus ring FR to adjust the state of the plasma generated in the inner space 10s. FIG. 3 is a partially enlarged cross sectional view of the supporting table and the focus ring of the plasma processing apparatus shown in FIG. 1. As shown in FIG. 3, in one embodiment, the focus ring FR is electrically connected to the lower electrode 18 through a conductor 22. The conductor 22 penetrates through the electrostatic chuck 20. The DC power supply 70A is electrically connected to the focus ring FR via the electrode plate 21, the lower electrode 18 and the conductor 22. The DC power supply 70A may be electrically connected to the focus ring FR via another electrical path without passing through the electrode plate 21, the lower electrode 18 and the conductor 22.

The plasma processing apparatus 1 further includes a measuring device 71A and a measuring device 72A. The measuring device 71A is a first measuring device in one embodiment and is configured to measure the current at the focus ring FR. The measuring device 72A is a second measuring device in one embodiment and is configured to measure the voltage at the focus ring FR. In one embodiment, the measuring device 71A and the measuring device 72A are provided in the DC power supply 70A. The measuring device 71A and the measuring device 72A may not be provided in the DC power supply 70A.

The plasma processing apparatus 1 further includes a DC power supply 70B. The DC power supply 70B is electrically connected to the upper electrode 30. The DC power supply 70B generates a negative DC voltage to be applied to the upper electrode 30 to adjust the state of the plasma generated in the inner space 10s. The plasma processing apparatus 1 further includes a measuring device 71B and a measuring device 72B. The measuring device 71B is a first measuring device in one embodiment and is configured to measure the current at the upper electrode 30. The measuring device 72B is a second measuring device in one embodiment and is configured to measure the voltage at the upper electrode 30. In one embodiment, the measuring device 71B and the measuring device 72B are provided in the DC power supply 70B. The measuring device 71B and the measuring device 72B may not be provided in the DC power supply 70B.

The plasma processing apparatus 1 may further include a control unit MC. The control unit MC is a computer including a processor, a storage device, an input device, a display device and the like, and controls the respective components of the plasma processing apparatus 1. Specifically, the control unit MC executes a control program stored in the storage device, and controls the respective components of the plasma processing apparatus 1 based on a recipe data stored in the storage device. In the plasma processing apparatus 1, a process specified by the recipe data is performed under the control of the control unit MC. Further, the plasma processing apparatus 1 can perform the method MT under the control of the control unit MC. In performing the method MT, the control unit MC controls at least one of the DC power supply 70A and the DC power supply 70B.

Hereinafter, the case of performing the method MT by using the plasma processing apparatus 1 will be described in detail as an example. Further, the control operation of the control unit MC in performing the method MT will be described. In the following description, each or both of the focus ring FR and the upper electrode 30 may be referred to as an “electrode E.” Each or both of the DC power supply 70A and the DC power supply 70B may be referred to as a “DC power supply 70.” Each or both of the measuring device 71A and the measuring device 71B may be referred to as a “measuring device 71.” Each or both of the measuring device 72A and the measuring device 72B may be referred to as a “measuring device 72.”

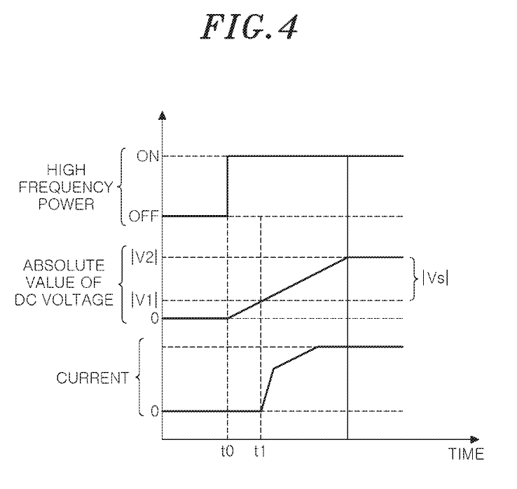

Hereinafter, FIGS. 1 and 4 will be referred to. FIG. 4 is a timing chart related to the method MT shown in FIG. 1. In the timing chart of FIG. 4, the horizontal axis represents time. In the timing chart of FIG. 4, the ON state of the high frequency power on the vertical axis indicates that the first high frequency power and/or the second high frequency power is supplied for plasma generation. In the timing chart of FIG. 4, the OFF state of the high frequency power on the vertical axis indicates that neither the first high frequency power nor the second high frequency power is supplied and no plasma is generated. In the timing chart of FIG. 4, the absolute value of the DC voltage on the vertical axis represents the absolute value of the DC voltage at the electrode E of the plasma processing apparatus. Further, in the timing chart of FIG. 4, the current on the vertical axis represents the value of the current at the electrode E of the plasma processing apparatus.

In a step ST1 of the method MT, plasma generation is started. Specifically, in a state where a gas is supplied to the inner space 10s, the supply of the first high frequency power and/or the second high frequency power is started to generate plasma of the gas. In the timing chart of FIG. 4, the plasma generation in the step ST1 is started at time to. In other words, the supply of the first high frequency power and/or the second high frequency power is started at time t0. In the step ST1, the first high frequency power supply 61 and the second high frequency power supply 62 are controlled by the control unit MC. The plasma generation started by executing the step ST1 continues until the plasma processing on the substrate W is completed. The plasma generation started by executing the step ST1 continues at least until the step ST4 is completed.

Next, a step ST2 is executed during the plasma generation started in the step ST1. In the step ST2, the absolute value of the negative DC voltage applied from the DC power supply 70 to the electrode E of the plasma processing apparatus 1 is increased. An increasing rate of the absolute value of the negative DC voltage in the step ST2 is preset. In the timing chart of FIG. 4, the application of the negative DC voltage to the electrode E is started from time t0, and the absolute value of the negative DC voltage is gradually increased as time elapses.

In the step ST2, when a negative DC voltage is applied to the focus ring FR, the absolute value of the negative DC voltage applied from the DC power supply 70A to the focus ring FR is increased. The control unit MC controls the DC power supply 70A to increase the absolute value of the negative DC voltage applied to the focus ring FR. In the step ST2, when a negative DC voltage is applied to the upper electrode 30, the absolute value of the negative DC voltage applied from the DC power supply 70B to the upper electrode 30 is increased. The control unit MC controls the DC current power supply 70B to increase the absolute value of the negative DC voltage applied to the upper electrode 30.

In a step ST3, a first voltage value (V1 in the timing chart of FIG. 4) is specified. The first voltage value is specified by the control unit MC. The first voltage value is a voltage value measured at the electrode E when the current starts to flow in the electrode E during the execution of the step ST2, i.e., during the increase of the absolute value of the negative DC voltage applied to the electrode E. In the timing chart of FIG. 4, this time is indicated by time t1. The control unit MC specifies this time as time at which a current greater than or equal to a predetermined value starts to flow in the electrode E from the measurement value obtained by the measuring device 71, i.e., the current measured at the electrode E. This predetermined value is set to, e.g., 0.001 [A]. The control unit MC specifies the first voltage value as the voltage measured at the electrode E at the specified time by using the measuring device 72. This time can be specified by any method as long as the time at which the current starts to flow in the electrode E can be specified. For example, this time may be specified as time at which a differential value of the current at the electrode E reaches a maximum value.

When the negative DC voltage is applied to the focus ring FR in the step ST3, the control unit MC specifies time at which a current greater than or equal to a predetermined value starts to flow in the focus ring FR from the measurement value obtained by the measuring device 71A, i.e., the current measured at the focus ring FR. The control unit MC specifies the voltage measured at the focus ring FR at the specified time as the first voltage value by using the measuring device 72A.

When the negative DC voltage is applied to the upper electrode 30 in the step ST3, the control unit MC specifies time at which a current greater than or equal to a predetermined value starts to flow in the upper electrode 30 from the measurement value obtained by the measuring device 71B, i.e., the current measured at the upper electrode 30. The control unit MC specifies the voltage measured at the upper electrode 30 at the specified time as the first voltage value by using the measuring device 72B.

Next, in a step ST4, the value of the DC voltage applied from the DC power supply 70 to the electrode E is set to a second voltage value (V2 in the timing chart of FIG. 4). In the step ST4, the control unit MC controls the DC power supply 70 to set the value of the DC voltage applied to the electrode E to the second voltage value. The second voltage value is the sum of the first voltage value (V1 in the timing chart of FIG. 4) and a specified value (Vs in the timing chart of FIG. 4). The specified value may be given as a part of the recipe data or may be inputted by an operator.

In the step ST4, as shown in FIG. 4, the value of the negative DC voltage applied from the DC power supply 70 to the electrode E may be gradually changed to be closer to the second voltage value as time elapses. Alternatively, in the step ST4, the value of the negative DC voltage applied from the DC power supply 70 to the electrode E may be set to the second voltage value immediately after the time at which the current starts to flow in the electrode E or immediately after the time at which the second voltage value is obtained.

When the negative DC voltage is applied to the focus ring FR in the step ST4, the controller MC controls the DC power supply 70A to set the value of the DC voltage applied to the focus ring FR to the second voltage value. The control unit MC obtains the second voltage value of the DC voltage applied to the focus ring FR as the sum of the first voltage value at the focus ring FR and the specified value for the focus ring FR.

When the negative DC voltage is applied to the upper electrode 30 in the step ST4, the controller MC controls the DC power supply 70B to set the value of the DC voltage applied to the upper electrode 30 to the second voltage value. The control unit MC obtains the second voltage value of the DC voltage applied to the upper electrode 30 as the sum of the first voltage value at the upper electrode 30 and the specified value for the upper electrode 30.

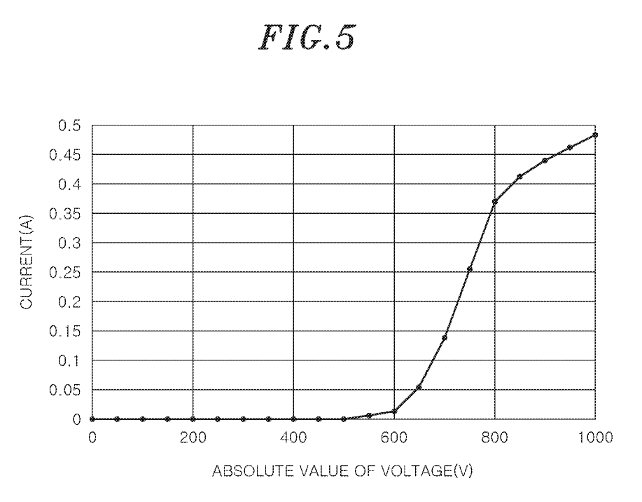

Hereinafter, FIG. 5 will be referred to. FIG. 5 is a graph showing the relation between the absolute value of the negative DC voltage at the focus ring of the plasma processing apparatus shown in FIG. 1 and the current at the focus ring. The graph shown in FIG. 5 was obtained by measuring the current at the focus ring FR while increasing the absolute value of the negative DC voltage applied from the DC power supply 70A to the focus ring FR during the generation of the plasma in the inner space 10s of the plasma processing apparatus 1. In the graph shown in FIG. 5, the horizontal axis represents the absolute value of the negative DC voltage applied to the focus ring FR from the DC power supply 70A, and the vertical axis represents the current at the focus ring FR.

As shown in FIG. 5, no current flows in the focus ring FR when the negative DC voltage having an absolute value smaller than a reference value (600 V in FIG. 5) is applied to the focus ring FR from the DC power supply 70A. Therefore, the state of the plasma cannot be adjusted even when the negative DC voltage having an absolute value smaller than the reference value is applied from the DC power supply 70A to the focus ring FR. As described above, the second voltage value is the sum of the first voltage value and the specified value. The first voltage value is the voltage value measured at the electrode E when the current starts to flow in the electrode E during the increase of the absolute value of the DC voltage. Therefore, when the second voltage value is applied to the electrode E, the current corresponding to the specified value flows to the electrode E. As a result, the state of the plasma in the inner space 10s is reliably adjusted.

While various embodiments have been described, the present disclosure can be variously modified without being limited to the above-described embodiments. For example, the plasma processing apparatus 1 does not necessarily include both of the DC power supply 70A and the DC power supply 70B, and may include at least one of the DC power supply 70A and the DC power supply 70B.

The method MT can be performed by using any plasma processing apparatus as long as it is possible to apply a negative DC voltage from the DC power supply to the electrode forming a part of the chamber or provided in the inner space. Such a plasma processing apparatus may be an inductively coupled plasma processing apparatus, a plasma processing apparatus using a surface wave such as a microwave for plasma generation, or the like.

While the present disclosure has been shown and described with respect to the embodiments, it will be understood by those skilled in the art that various changes and modifications may be made without departing from the scope of the present disclosure as defined in the following claims.

What is claimed is:

1. A method for applying a DC voltage to an electrode of a plasma processing apparatus, the method comprising:
generating plasma of a gas in an inner space of a chamber;
increasing an absolute value of a negative DC voltage applied from a DC power supply to the electrode that forms a part of the chamber or is provided in the inner space during the generation of the plasma;
specifying a first voltage value that is a voltage value measured at the electrode when a current starts to flow in the electrode during the increase of the absolute value of the negative DC voltage; and
setting a value of the DC voltage applied from the DC power supply to the electrode during the generation of the plasma to a second voltage value that is a sum of the first voltage value and a specified value.

2. The method of claim 1, wherein the electrode is a focus ring arranged to surround a substrate in the inner space.

3. The method of claim 1, wherein the plasma processing apparatus is a capacitively coupled plasma processing apparatus and includes: a supporting table configured to support a substrate in the inner space and having a lower electrode; and the chamber including an upper electrode provided above the supporting table, and
wherein the electrode to which the DC voltage is applied is the upper electrode.

4. The method of claim 2, wherein the plasma processing apparatus is a capacitively coupled plasma processing apparatus and includes: a supporting table configured to support a substrate in the inner space and having a lower electrode; and the chamber including an upper electrode provided above the supporting table, and
wherein the electrode to which the DC voltage is applied is the upper electrode.

5. A plasma processing apparatus comprising:
a chamber;
a high frequency power supply configured to generate a high frequency power for exciting a gas supplied to an inner space of the chamber;
a DC power supply electrically connected to an electrode that forms a part of the chamber or is provided in the inner space;
a first measuring device configured to measure a current at the electrode;
a second measuring device configured to measure a voltage at the electrode; and
a control unit configured to control a negative DC voltage applied from the DC power supply to the electrode,
wherein the control unit performs processes including:
controlling the DC power supply to increase an absolute value of the negative DC voltage applied to the electrode during generation of plasma in the inner space;
specifying a time at which a current starts to flow in the electrode from the measurement value obtained by the first measuring device during the increase of the absolute value of the DC voltage and specifying a first voltage value at the electrode at the specified time by using the second measuring device; and
controlling the DC power supply to set a value of the DC voltage applied to the electrode during the generation of the plasma to a second voltage value that is a sum of the first voltage value and a specified value.

6. The plasma processing apparatus of claim 5, wherein the electrode is a focus ring arranged to surround a substrate in the inner space.

7. The plasma processing apparatus of claim 5, wherein the plasma processing apparatus is a capacitively coupled plasma processing apparatus and includes: a supporting table configured to support a substrate in the inner space and having a lower electrode; and the chamber including an upper electrode provided above the support table, and
wherein the electrode to which the DC voltage is applied is the upper electrode.

8. The plasma processing apparatus of claim 6, wherein the plasma processing apparatus is a capacitively coupled plasma processing apparatus and includes: a supporting table configured to support a substrate in the inner space and having a lower electrode; and the chamber including an upper electrode provided above the support table, and
wherein the electrode to which the DC voltage is applied is the upper electrode.
